(19) United States
(12) Patent Application Publication
(10) Pub. No.: US 2026/0222002 A1
(43) Pub. Date: Jul. 30, 2026

(54) ELECTRONIC CONTROL SYSTEM

(71) Applicant: Panasonic Intellectual Property Management Co., Ltd., Osaka (JP)

(72) Inventors: TAKESHI FUJII, Osaka (JP); YASUHIKO SASAKI, Hokkaido (JP); KEN YANAI, Hokkaido (JP)

(21) Appl. No.: 19/145,156

(22) PCT Filed: Jan. 31, 2024
(86) PCT No.: PCT/JP2024/003113

§ 371 Date: Jul. 1, 2025

(30) Foreign Application Priority Data
Feb. 10, 2023 (JP) 2023-019243

(51) Int. Cl. H04B 1/40; H01C 7/10; H01G 4/30

(52) U.S. Cl. CPC H04B 1/40; H01C 7/10; H01G 4/30

(57) ABSTRACT

An electronic control system includes a master circuit and a slave circuit connected to the master circuit via a bus cable. The master circuit includes a first microcontroller, a first transceiver IC connected to the first microcontroller, a first communication terminal connected to the bus cable, and a first varistor provided in a line connecting a ground to a transmission path which connects the first transceiver IC to the first communication terminal. The slave circuit includes a second microcontroller, a second transceiver IC connected to the second microcontroller, a second communication terminal connected to the bus cable, and a second varistor provided in a line connecting a ground to a transmission path which connects the second transceiver IC to the second communication terminal.

### TECHNICAL FIELD

The present disclosure relates to an electronic control system configured to perform communication based on LIN or CXPI.

### BACKGROUND ART

A communication system configured to perform communication based on a communication standard such as a local interconnect network (LIN) or a clock extension peripheral interface (CXPI) is known. PTL 1 discloses a signal output circuit configured to output a signal according to a level of a control signal as an example of a communication driver used for in-vehicle communication.

### CITATION LIST

### Patent Literature

PTL 1: Japanese Patent Laid-Open Publication No. 2017-158010

### SUMMARY OF INVENTION

Even the signal output circuit disclosed in PTL 1 may cause communication quality to deteriorate when communication is performed between a master circuit and a slave circuit based on the LIN or the CXPI.

An electronic control system according to an aspect of the present disclosure includes a master circuit and a slave circuit connected to the master circuit via a bus cable. The master circuit includes a first microcontroller, a first transceiver integrated circuit (IC) connected to the first microcontroller, a first communication terminal connected to the bus cable, and a first varistor provided in a line connecting a ground to a transmission path which connects the first transceiver IC to the first communication terminal. The slave circuit includes a second microcontroller, a second transceiver IC connected to the second microcontroller, a second communication terminal connected to the bus cable, and a second varistor provided in a line connecting a ground to a transmission path which connects the second transceiver IC to the second communication terminal.

The electronic control system of the present disclosure prevents deterioration of communication quality when performing communication between the master circuit and the slave circuit.

### BRIEF DESCRIPTION OF DRAWINGS

FIG. 1 is a circuit diagram of an electronic control system of Comparative Example 1.

FIG. 2 is a circuit diagram of an electronic control system of Comparative Example 2.

FIG. 3 is a circuit diagram of an electronic control system according to Exemplary Embodiment 1.

FIG. 4 is a schematic diagram of an example of a first varistor provided in a master circuit and a second varistor provided in a slave circuit of the electronic control system.

FIG. 5 illustrates a resistance, a capacitance, and a time constant defined by the LIN communication standard.

FIG. 6 illustrates a circuit for performing an ESD test.

FIG. 7 illustrates an ESD resistance of a multi-layer ceramic capacitor.

FIG. 8 illustrates an ESD resistance of a multi-layer ceramic varistor.

FIG. 9 illustrates a circuit for measuring a static electricity inhibit voltage.

FIG. 10 illustrates static electricity inhibit voltages of the multi-layer ceramic capacitor and the multi-layer ceramic varistor.

FIG. 11 illustrates an enlarged part of FIG. 10 along a vertical axis thereof.

FIG. 12 is a circuit diagram of an electronic control system according to Exemplary Embodiment 2.

FIG. 13 illustrates an example of a capacitor and a first varistor provided in a master circuit and a second varistor provided in a slave circuit of the electronic control system.

### DESCRIPTION OF EMBODIMENT

### Background of Present Disclosure

The LIN (Local Interconnect Network) and CXPI (Clock Extension Peripheral Interface) are known as in-vehicle communication standards. The LIN and CXPI are used, for example, as sub-networks of a local interconnect network (CAN) in an in-vehicle network.

The LIN is a communication standard designed for reducing a cost of an in-vehicle communication network, and a communication specification thereof is defined by ISO17987. The LIN communication is adopted for control of a sensor, an actuator, or the like that does not require a large amount of information or a high communication speed as in power train control or chassis control.

The CXPI is a communication standard designed based on the LIN for the purpose of improving responsiveness more than the LIN, and a communication specification thereof is defined by the ISO20794. The CXPI communication is adopted for control of a human machine interface (HMI) in which a person directly operates a machine for control of, e.g., a switch, a wiper, and a light of an automobile.

The LIN and CXPI have common hardware specifications (standards). An electronic control system based on the LIN or CXPI includes a master node and slave nodes which are connected to the master node with a bus. Hereinafter, the master node may be referred to as a master circuit, and the slave node may be referred to as a slave circuit.

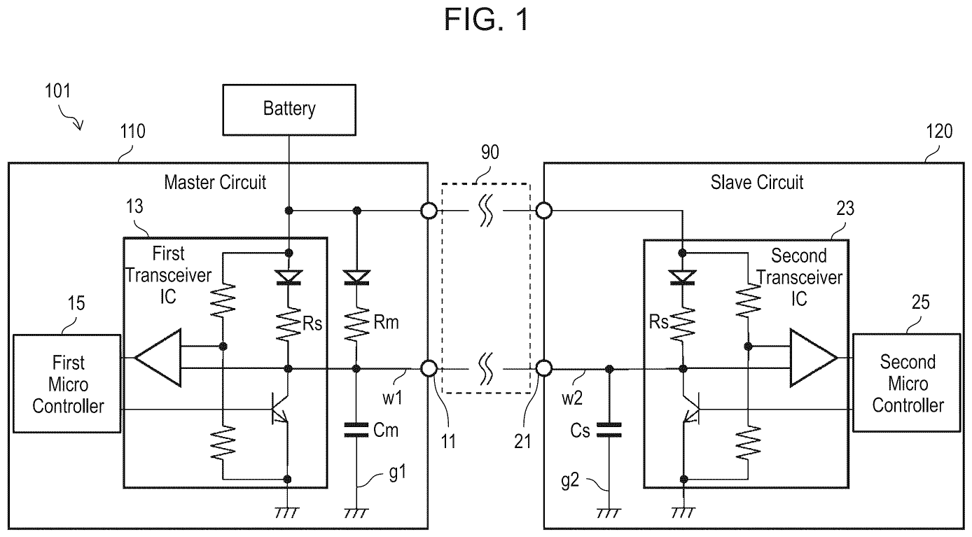

FIG. 1 is a circuit diagram of an electronic control system 101 of Comparative Example 1.

The electronic control system 101 of Comparative Example 1 includes a master circuit 110 and a slave circuit 120 connected to the master circuit 110 via a bus cable 90.

The master circuit 110 includes a first microcontroller 15, a first transceiver IC 13 connected to the first microcontroller 15, a first communication terminal 11 connected to the bus cable 90, and a first capacitor Cm provided in a line g1 connecting a ground to a transmission path w1 which connects the first transceiver IC 13 to the first communication terminal 11.

The slave circuit 120 includes a second microcontroller 25, a second transceiver IC 23 connected to the second microcontroller 25, a second communication terminal 21 connected to the bus cable 90, and a second capacitor Cs provided in a line g2 connecting the ground to a transmission path w2 which connects the second transceiver IC 23 to the second communication terminal 21.

A circuit constituting an in-vehicle electronic control system is required to have electro-static discharge (ESD) resistance that satisfies an ESD test defined by ISO10605 and IEC61000-4-2. In addition, the circuit constituting the in-vehicle electronic control system is required to have noise resistance that satisfies an immunity (electromagnetic susceptibility) test defined by ISO11452-4.

The master circuit 110 and the slave circuit 120 of Comparative Example 1 includes the capacitors Cm and Cs that satisfy a time constant of a communication signal line to be described later, respectively, and thus, may satisfy requirements for basic communication quality. However, for example, in a case that the capacitors Cm and Cs are multi-layer ceramic capacitors, when a high voltage is applied due to static electricity, air discharge occurs between external terminals, possibly causing a malfunction in a semiconductor component mounted near the multi-layer ceramic capacitor. In addition, upon having a high voltage applied due to static electricity to the multi-layer ceramic capacitor, the high voltage may destroy internal dielectric layers of the multi-layer ceramic capacitor, resulting in a short circuit. Therefore, in a circuit in which a capacitor alone is mounted as in Comparative Example 1, requirements for the ESD resistance are hardly satisfied. That is, the circuit of Comparative Example 1 has low ESD resistance.

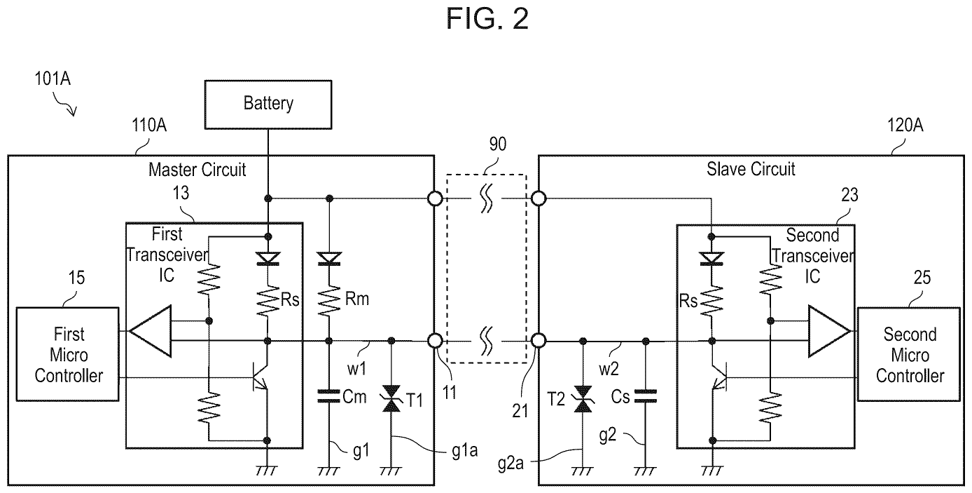

FIG. 2 is a circuit diagram of an electronic control system 101A of Comparative Example 2.

The electronic control system 101A of Comparative Example 2 includes a master circuit 110A and a slave circuit 120A connected to the master circuit 110A via the bus cable 90.

The master circuit 110A of Comparative Example 2 further includes a first Zener diode T1 in the master circuit 110 of Comparative Example 1. The slave circuit 120A of Comparative Example 2 further includes a second Zener diode T2 in the slave circuit 120 of Comparative Example 1. Specifically, the first Zener diode T1 is provided in a line g1a connecting a ground to the transmission path w1 which connects the first transceiver IC 13 to the first communication terminal 11. The second Zener diode T2 is provided in a line g2a connecting the ground to the transmission path w2 which connects the second transceiver IC 23 to the second communication terminal 21.

The master circuit 110A and the slave circuit 120A of Comparative Example 2 include the Zener diodes T1 and T2 for countermeasures against static electricity, respectively, thereby satisfying the requirements for the ESD resistance. However, the Zener diodes T1 and T2 may cause a reverse recovery current to flow and interrupt communication when a high alternating-current (AC) voltage is applied in a typical bulk current injection (BCI) test for evaluating noise resistance of an in-vehicle electronic device, and the circuits shown in Comparative Example 2 have EWD resistance but has low noise resistance.

In the BCI test, a high-frequency interfering current is injected into a harness with a current injection probe (BCI probe), and immunity (electromagnetic susceptibility) of electronic devices is evaluated. Conditions are set by automatic vehicle manufacturers and ISO11452-4. In the ISO11452-4, an interfering current injection in a frequency range from 1 MHz to 400 MHz is set as a test condition, and noise resistance that does not cause a communication failure, such as a communication error, even when such an interfering current is applied is required.

The electronic control system of the present disclosure has the following configuration to satisfy the requirements for the ESD resistance and the noise resistance, that is, in order to prevent deterioration in communication quality when the communication is performed between the master circuit and the slave circuit based on the LIN or the CXPI.

Exemplary embodiments will be described below with reference to the drawings.

Each of the embodiments to be described below shows a specific example of the present disclosure. The numerical values, shapes, materials, components, arrangement positions and connection forms of the components, steps, the order of the steps, and the like shown in the following embodiments are mere examples, and are not intended to limit the present disclosure. In addition, among the components in the following embodiments, components not recited in any one of the independent claims are described as any components.

In addition, in the present specification, a numerical range is not an expression representing only a strict meaning, and is an expression meaning that a substantially equivalent range, for example, a difference of about several percents is also included.

In addition, each drawing is a schematic diagram in which emphasis, omission, or ratio adjustment is appropriately performed in order to illustrate the present disclosure, is not necessarily strictly illustrated, and may be different from an actual shape, positional relation, and ratio. In the drawings, substantially the same components are denoted by the same reference numerals, and redundant description may be omitted or simplified.

### Exemplary Embodiment 1

### Configuration of Electronic Control System

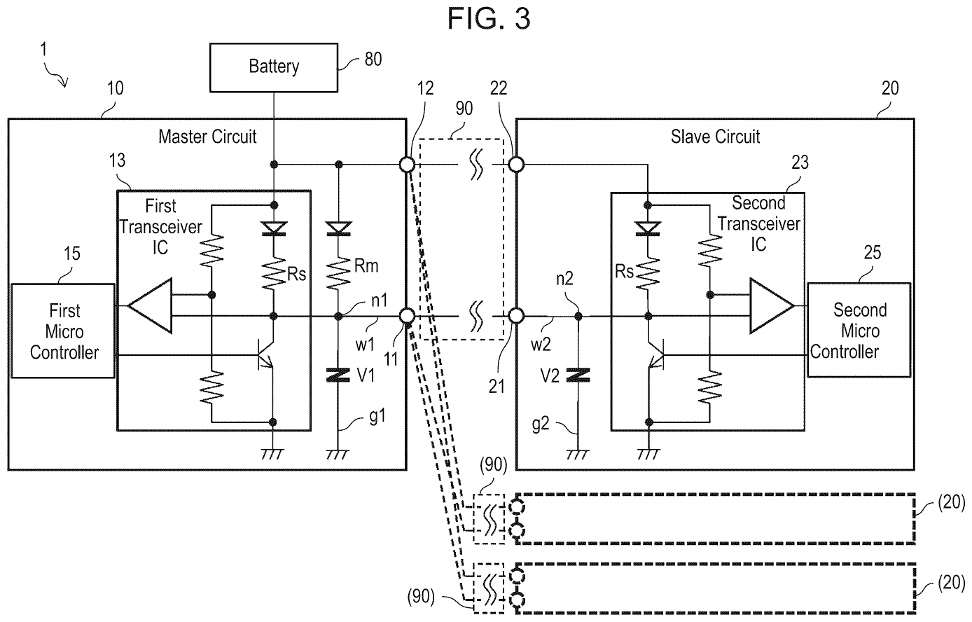

A configuration of the electronic control system according to Exemplary Embodiment 1 will be described with reference to FIG. 3.

FIG. 3 is a circuit diagram of an electronic control system 1 according to Embodiment 1.

The electronic control system 1 is configured to control electric devices in a vehicle, and is installed to the vehicle. As illustrated in FIG. 3, the electronic control system 1 includes a master circuit 10 and slave circuits 20 that are connected to the master circuit 10 with buses. The master circuit 10 is connected to each of the slave circuits 20 via a corresponding one of bus cables 90. The master circuit 10 is connected communicatively to the slave circuits 20 with one wire, a single wire, out of plural of wires provided in the bus cable 90, that is, a single wire. Each slave circuits 20 is connected to the master circuit 10 with a corresponding one of the bus cables 90. Only a single slave circuit 20 may be connected to the master circuit 10.

The master circuit 10 includes the first microcontroller 15, the first transceiver IC 13, a first communication terminal 11, a first power supply terminal 12, and a first varistor V1. The master circuit 10 includes a master resistor Rm. The master circuit 10 is connected to an external battery 80. A voltage of the battery 80 is, e.g., 12 V.

The first communication terminal 11 and the first power supply terminal 12 are provided in a connector of the master circuit 10 and are connected to the bus cable 90. A communication signal for performing communication between the master circuit 10 and the slave circuit 20 is input to and output from the first communication terminal 11. The first power supply terminal 12 is electrically connected to the battery 80. The voltage supplied from the battery 80 is output from the first power supply terminal 12.

The first microcontroller 15 is configured to control an overall operation of the electronic control system 1 including the slave circuits 20, and executes various processing.

The first transceiver IC 13 is connected to the first microcontroller 15. The first transceiver IC 13 includes a comparator, a transistor, a pull-up resistor Rs, and a diode. The comparator has one input terminal connected to the battery 80 via a resistor, another input terminal connected to the first communication terminal 11, and an output terminal connected to an input port of the first microcontroller 15. The one input terminal of the comparator is connected to an emitter of the transistor via another resistor. The base of the transistor is connected to an output port of the first microcontroller 15, and the emitter of the transistor is connected to the ground. A collector of the transistor is connected to the pull-up resistor Rs and is connected to a path inside the IC connecting another input terminal of the comparator and the first communication terminal 11. The pull-up resistor Rs has one end connected to the battery 80 via the diode, and another end connected to the collector of the transistor and the path inside the IC. The first transceiver IC 13 is connected to the battery 80 via the pull-up resistor Rs and the diode, and receives a voltage for communication supplied from the battery 80.

The first transceiver IC 13 converts a communication signal received via the bus cable 90 into a digital signal, and outputs the digital signal to the first microcontroller 15. In addition, the first transceiver IC 13 transmits, to the slave circuit 20 via the bus cable 90, a communication signal generated based on the output from the first microcontroller 15.

The first varistor V1 an element for preventing deterioration in communication quality when the communication is performed between the master circuit 10 and the slave circuit 20. The first varistor V1 is provided in the line g1 connecting the ground to the transmission path w1 which connects the first transceiver IC 13 to the first communication terminal 11. The first varistor V1 has one end connected to a node n1 on the transmission path w1 between the first communication terminal 11 and the first transceiver IC 13, and another end connected to the ground. The ground is a reference potential of the electronic control system 1 and is electrically connected to, e.g., a body earth of the vehicle. The first varistor V1 is configured to allow a current to flow from the node n1 to the ground upon being conducted under a predetermined voltage condition. Therefore, even when a large current flows through the transmission path w1, the current is prevented from flowing into the first transceiver IC 13, thereby protecting the first transceiver IC 13.

The master resistor Rm has one end connected to the battery 80 and another end connected to the node n1 on the transmission path w1 which connects the first transceiver IC 13 to the first communication terminal 11. The master resistor Rm is connected in parallel to the pull-up resistor Rs in the first transceiver IC 13, and constitutes a combined resistor together with the pull-up resistor Rs. The master resistor Rm has a smaller resistance than the pull-up resistor Rs.

The slave circuit 20 includes the second microcontroller 25, the second transceiver IC 23, the second communication terminal 21, a second power supply terminal 22, and a second varistor V2. The slave circuit 20 does not include the master resistor Rm as in the master circuit 10. The slave circuit 20 is connected to the battery 80 via the bus cable 90 and the master circuit 10.

The second communication terminal 21 and the second power supply terminal 22 are provided in a connector of the slave circuit 20 and are connected to the bus cable 90. A communication signal for performing communication between the master circuit 10 and the slave circuit 20 is input to and output from the second communication terminal 21. The second power supply terminal 22 is connected to the first power supply terminal 12 via the bus cable 90. The second power supply terminal 22 receives the voltage output from the battery 80 via the master circuit 10 and the bus cable 90. That is, a wire in the bus cable 90 between the first communication terminal 11 and the second communication terminal 21 is a communication line, and a wire in the bus cable 90 between the first power supply terminal 12 and the second power supply terminal 22 is a power supply line.

The second microcontroller 25 is a controller different from the first microcontroller 15. The second microcontroller 25 executes various application processing according to in-vehicle devices. For example, in the case that the in-vehicle devices are infotainment devices (for example, a car navigation device and a display audio), the second microcontroller 25 executes an image signal processing or an audio signal processing.

The second transceiver IC 23 is connected to the second microcontroller 25. The second transceiver IC 23 is an IC having the same circuit configuration as the first transceiver IC 13. The second transceiver IC 23 includes a comparator, a transistor, the pull-up resistor Rs, and a diode. The comparator has one input terminal connected to the second power supply terminal 22 via a resistor, another input terminal connected to the second communication terminal 21, and an output terminal connected to an input port of the second microcontroller 25. The one input terminal of the comparator is connected to an emitter of the transistor via another resistor. The base of the transistor is connected to an output unit of the second microcontroller 25, and the emitter of the transistor is connected to the ground. A collector of the transistor is connected to the pull-up resistor Rs and is connected to a path inside the IC connecting another input terminal of the comparator to the second communication terminal 21. The pull-up resistor Rs has one end connected to the second power supply terminal 22 via the diode, and another end connected to the collector of the transistor and the path inside the IC. The second transceiver IC 23 is connected to the second power supply terminal 22 via the pull-up resistor Rs and the diode, and receives a voltage for communication output from the second power supply terminal 22.

The second transceiver IC 23 converts a communication signal received via the bus cable 90 into a digital signal, and outputs the digital signal to the second microcontroller 25. In addition, the second transceiver IC 23 transmits, to the master circuit 10 via the bus cable 90, a communication signal generated based on the output from the second microcontroller 25.

The second varistor V2 is an element for preventing the deterioration in communication quality when the communication is performed between the master circuit 10 and the slave circuit 20. The second varistor V2 is provided in the line g2 connecting the ground to the transmission path w2 which connects the second transceiver IC 23 to the second communication terminal 21. The second varistor V2 has one end connected to a node n2 on the transmission path w2 between the second communication terminal 21 and the second transceiver IC 23, and another end connected to the ground. The second varistor V2 allows a current to flow from the node n2 to the ground by being conducted under a predetermined voltage condition. Therefore, even when a large current flows through the transmission path w2, the current is prevented from flowing into the second transceiver IC 23, thereby protecting the second transceiver IC 23.

The electronic control system 1 according to the present embodiment includes the master circuit 10 and the slave circuits 20 connected to the master circuit 10 via the bus cables 90. The master circuit 10 includes the first microcontroller 15, the first transceiver IC 13 connected to the first microcontroller 15, the first communication terminal 11 connected to the bus cable 90, and the first varistor V1 provided in the line g1 connecting the ground to the transmission path w1 which connects the first transceiver IC 13 to the first communication terminal 11. The slave circuit 20 includes the second microcontroller 25, the second transceiver IC 23 connected to the second microcontroller 25, the second communication terminal 21 connected to the bus cable 90, and the second varistor V2 provided in the line g2 connecting the ground to the transmission path w2 which connects the second transceiver IC 23 to the second communication terminal 21.

The first varistor V1 is thus provided in the line g1 connecting the transmission path w1 to the ground, and the second varistor V2 is provided in the line g2 connecting the transmission path w2 to the ground. Even when a large current flows through the transmission path, this configuration prevents the current from flowing into the transceiver IC. This prevents the deterioration in communication quality when the communication is performed between the master circuit 10 and the slave circuit 20.

### Configurations of Varistors Provided in Master Circuit and Slave Circuit

Configurations of the first varistor V1 and the second varistor V2 provided in the master circuit 10 and the slave circuit 20 will be described.

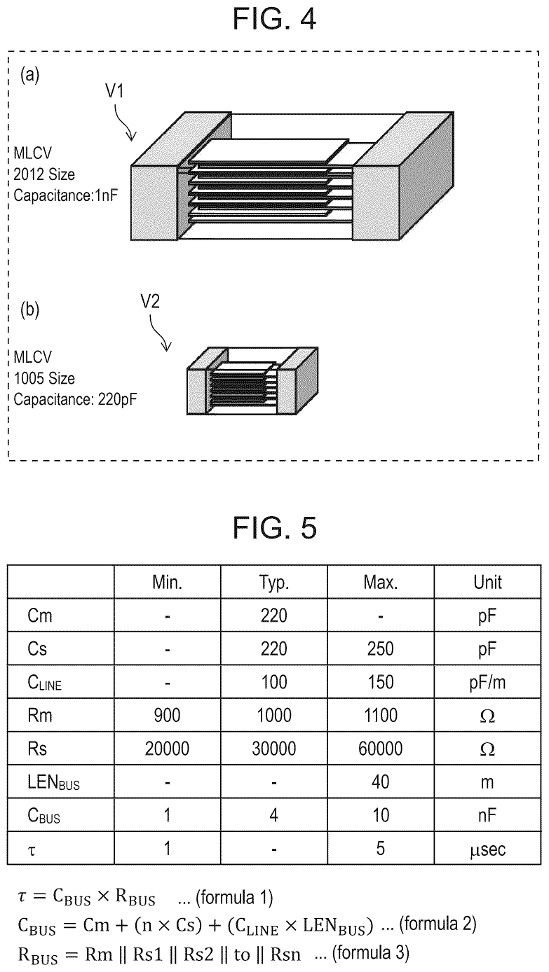

FIG. 4 is a schematic diagram of an example of the first varistor V1 provided in the master circuit 10 and the second varistor V2 provided in the slave circuit 20 of the electronic control system 1. FIG. 4 is a perspective view of internal electrodes visually shown from outside of the varistor.

Each of the first varistor V1 and the second varistor V2 is a multi-layer ceramic varistor having a rectangular parallelepiped chip shape. The multi-layer ceramic varistor is formed by stacking, pressing, and sintering plural ceramic layers and plural ceramic layers with internal electrodes, and then, providing first and second external terminals connected to first and second internal electrodes, respectively. The first internal electrode faces the second internal electrode face in a stacking direction across one of the ceramic layers made of nonlinear resistance material.

In accordance with the present embodiment, the second varistor V2 has a smaller size than the first varistor V1. Here, the size of the varistor means a length, a width, and a height of the varistor. The smaller size means that at least one of the length, the width, and the height of one varistor is smaller than that of the other varistor. For example, the size of the first varistor V1 is a 2012 size (length 2.0 mm, width 1.25 mm, height 0.8 mm) (see FIG. 4(a)). The size of the second varistor V2 is a 1005 size (length 1.0 mm, width 0.5 mm, height 0.5 mm) (see FIG. 4(b)). Accordingly, a size of the slave circuit 20 disposed at an end of the vehicle may be smaller than a size of the master circuit 10. The size of the first varistor V1 may be a 1608 size (length 1.6 mm, width 0.8 mm, height 0.8 mm).

As for a varistor voltage of each varistor, a varistor voltage of the first varistor V1 is preferably 20 V or more and a varistor voltage of the second varistor V2 is preferably 20 V or more. The varistor voltage is a voltage of the multi-layer ceramic varistor when a current of 1 mA flows through the varistor. The varistor voltage upon increasing prevents a leakage current and reduces a current consumption accordingly while a varistor voltage upon decreasing enhances a static electricity inhibitory effect accordingly.

In the communication signal line using the LIN communication standard, a High voltage (in a range from 8 V to 18 V) which is a recessive of the communication signal and a Low voltage (0 V) which is a dominant are implemented by a 12 V battery power supply and a transceiver IC having a pull-up resistor. Therefore, in accordance with the present embodiment, the varistor voltages of the first varistor V1 and the second varistor V2 are higher than 18 V, which is a voltage upper limit of the communication signal, and are 20 V or more with a margin of error. For example, in order to enhance the static electricity inhibitory effect, the varistor preferably has a varistor voltage of 20 V or more and 27 V or less.

As for a capacitance of each varistor, the first varistor V1 preferably has a larger capacitance than the second varistor V2. In accordance with the present embodiment, for example, the capacitance of the first varistor V1 is 0.8 nF or more and 1.2 nF or less, and the capacitance of the second varistor V2 is 175 pF or more and 250 pF or less. The capacitance of the first varistor V1 larger than the capacitance of the second varistor V2 provides the electronic control system 1 with a wide application range.

An advantage of the capacitance of the first varistor V1 larger than the capacitance of the second varistor V2 will be described below. Hereinafter, the LIN will be described as an example, and the same applies to the CXPI.

FIG. 5 illustrates a resistance, a capacitance, and a time constant defined by the LIN communication standard.

Examples of the electronic control system based on the LIN communication standard include a system of Comparative Example 1 illustrated in FIG. 1. In the LIN communication standard, the maximum number of nodes connectable to the bus cable is 16 (for example, one master node and 15 slave nodes), and a maximum length of the bus cable is defined as 40 m. In addition, in order to ensure the communication quality, a time constant τ of the communication signal line ranges from 1 μsec to 5 μsec so that a transition time between the High voltage and the Low voltage of the communication signal is in a certain range.

The time constant τ of the communication signal line is calculated by multiplying a total capacitance C_{BUS} of the communication signal line by a total resistance R_{BUS} of the communication signal line as illustrated in Equation 1 shown in FIG. 5. The total capacitance C_{BUS} is obtained by summing up a capacitance of the capacitor Cm of the master node, capacitances of the capacitors Cs of n slave nodes, and a capacitance of the bus cable (=C_{LINE}×LEN_{BUS}) as illustrated in Equation 2. As illustrated in Equation 3, the total resistance R_{BUS} is calculated based on resistances of the resistance Rm and the pull-up resistor Rs of the master node and the pull-up resistors Rs of the n slave nodes in a parallel connection relation. In the LIN communication standard, the master resistor Rm has a resistance of 1 kΩ, the pull-up resistor Rs has a resistance of 30 kΩ, and a total capacitance of the capacitors and the bus cable 90 ranges from 1 nF to 10 nF.

Under such conditions, for example, in the case that the capacitances of the first varistor V1 and the second varistor V2 are both 220 pF, the time constant τ may not satisfy the standard when the number of nodes is small and a bus cable length is short. For example, in the case that the number of nodes is two and the bus cable length is 6 m or less, the case that the number of nodes is three and the bus cable length is 4 m or less, or the case that the number of nodes is four and the bus cable length is 2 m or less, the time constant τ becomes too small and does not satisfy the standard.

On the other hand, in the LIN communication standard, the capacitance of the capacitor of the master node is standardized to only a center value of 220 pF, and no upper limit value is defined.

Therefore, in accordance with the present embodiment, the capacitance of the first varistor V1 functioning as a capacitor in the master circuit 10 is increased to 1 nF, and the capacitance of the second varistor V2 functioning as a capacitor in the slave circuit 20 is 220 pF, which is the same as the standard. By thus increasing the capacitance of the first varistor V1, the capacitance of the capacitor Cm illustrated in Equation 2 increases. Therefore, even if the number (ranging from 2 to 16) of nodes or the bus cable length (ranging from 1 m to 40 m) changes within a range standardized by the LIN, the time constant τ is substantially within a predetermined range. the capacitance of 1 nF of the first varistor V1 of the master circuit 10 and the capacitance of 220 pF of the second varistor V2 of the slave circuit 20 widen selection ranges of the number of nodes and the bus cable length, and provide the electronic control system 1 with a wide application range.

In the case that the number of nodes is 16 and the bus cable length is 34 m or more, the time constant τ may become too large. In the case that the number of nodes and the bus cable length are used, for example, it is possible to solve the problem of the too large time constant τ by setting a capacitance value of the first varistor V1 to 0.8 nF. In addition, the capacitance of the second varistor V2 is not limited to 220 pF, and for example, may be 150 pF to satisfy the time constant τ defined by the standard.

### ESD Resistance of Varistor

An ESD resistance of the varistor will be described as compared with an ESD resistance of the capacitor.

In this example, a multi-layer ceramic capacitor (MLCC) as an example of a capacitor and a multi-layer ceramic varistor (MHLCV) as an example of a varistor will be described.

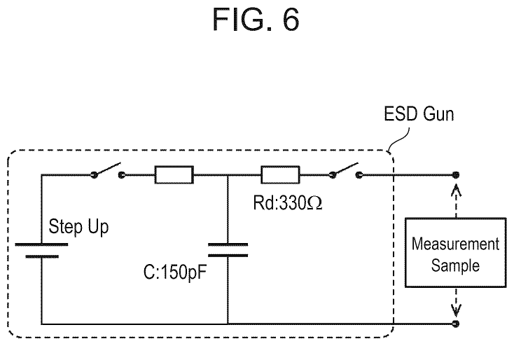

FIG. 6 illustrates a circuit for performing an ESD test.

FIG. 6 illustrates an equivalent circuit of an ESD gun used in the ESD test. A measurement sample to be tested is the MLCC or the MLCV.

In this test, an ESD voltage of 1 kV was applied to the measurement sample 100 times, and the presence or absence of characteristic deterioration of the measurement sample was examined. In addition, the same test was repeated by increasing the ESD voltage by 1 kV, and a voltage limit when the characteristic deterioration occurs was examined. The presence or absence of characteristic deterioration was determined based on whether a capacitance value of the measurement sample was within 10% of an initial capacitance value. In-vehicle electronic control systems may be required to withstand the number of times of applying the ESD voltage of 100 times and to have the ESD voltage indicating the voltage limit of 25 kV or more.

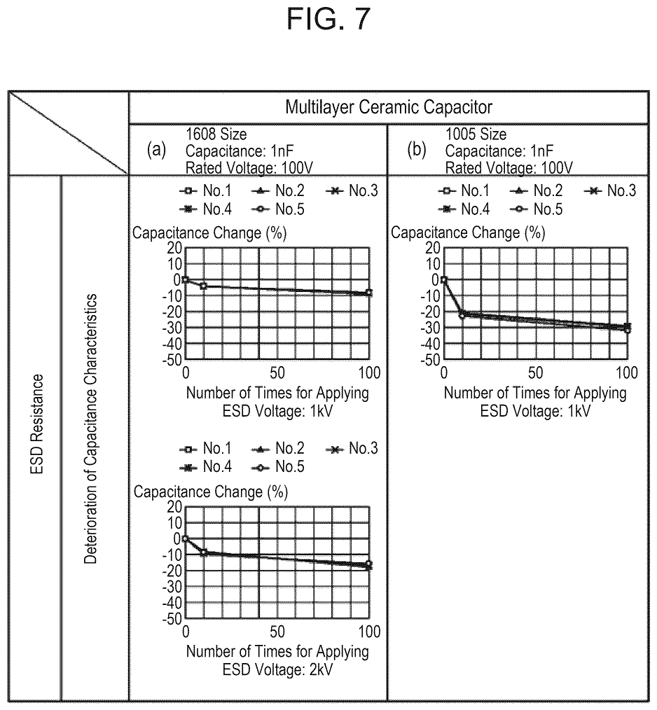

FIG. 7 illustrates the ESD resistance of the multi-layer ceramic capacitor.

FIG. 7(a) illustrates a multi-layer ceramic capacitor having a 1608 size and a capacitance of 1 nF used as a measurement sample. FIG. 7(b) illustrates a multi-layer ceramic capacitor having a 1005 size and a capacitance of 1 nF used as a measurement sample. As illustrated in FIG. 7(a), the multi-layer ceramic capacitor having the 1608 size and the capacitance of 1 nF satisfies an evaluation criteria of the number of times of application of 100 times at the ESD voltage of 1 kV, but does not satisfy an evaluation criteria of the number of times of application of 100 times at an ESD voltage of 2 kV. As illustrated in FIG. 7(b), the multi-layer ceramic capacitor having the 1005 size and the capacitance of 1 nF does not satisfy the evaluation criteria of the number of times of application of 100 times at the ESD voltage of 1 kV.

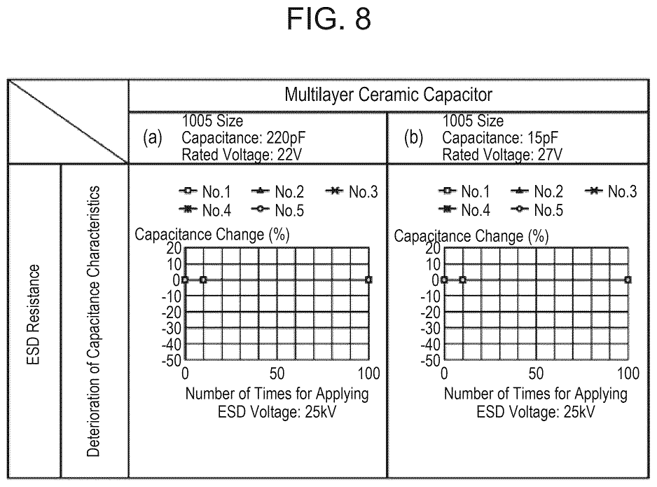

FIG. 8 illustrates an ESD resistance of the multi-layer ceramic varistor.

FIG. 8(a) illustrates a multi-layer ceramic varistor having a 1005 size and a capacitance of 220 pF used as a measurement sample. FIG. 8(b) illustrates a multi-layer ceramic varistor having a 1005 size and a capacitance of 15 pF used as a measurement sample. As illustrated in FIG. 8(a), the multi-layer ceramic varistor having the 1005 size and the capacitance of 220 pF satisfies the evaluation criteria of an ESD voltage of 25 kV and the number of times of application of 100 times. In addition, as illustrated in FIG. 8(b), the multi-layer ceramic varistor having the 1005 size and the capacitance of 15 pF also satisfies the evaluation criteria of the ESD voltage of 25 kV and the number of times of application of 100 times.

The multi-layer ceramic varistor thus has higher ESD resistance than the multi-layer ceramic capacitor. Therefore, the first varistor V1 and the second varistor V2, multi-layer ceramic varistors, functioning as capacitors enhance the ESD resistance of the electronic control system 1.

### Static Electricity Inhibit Voltage of Varistor

In order to protect the microcontroller and the transceiver IC constituting the electronic control system from static electricity noise, an electronic component used in the electronic control system is required to have a property of causing charges of static electricity to flow to the ground and reducing a voltage generated due to the static electricity. This property is determined by measuring a static electricity inhibit voltage of the measurement sample. The static electricity inhibit voltage indicates a residual voltage accumulated in the measurement sample, and indicates that the smaller the residual voltage is, the more difficult it is for static electricity to be generated, that is, the static electricity noise can be reduced.

A static electricity inhibit voltage of the varistor will be described below as compared with a static electricity inhibit voltage of the capacitor.

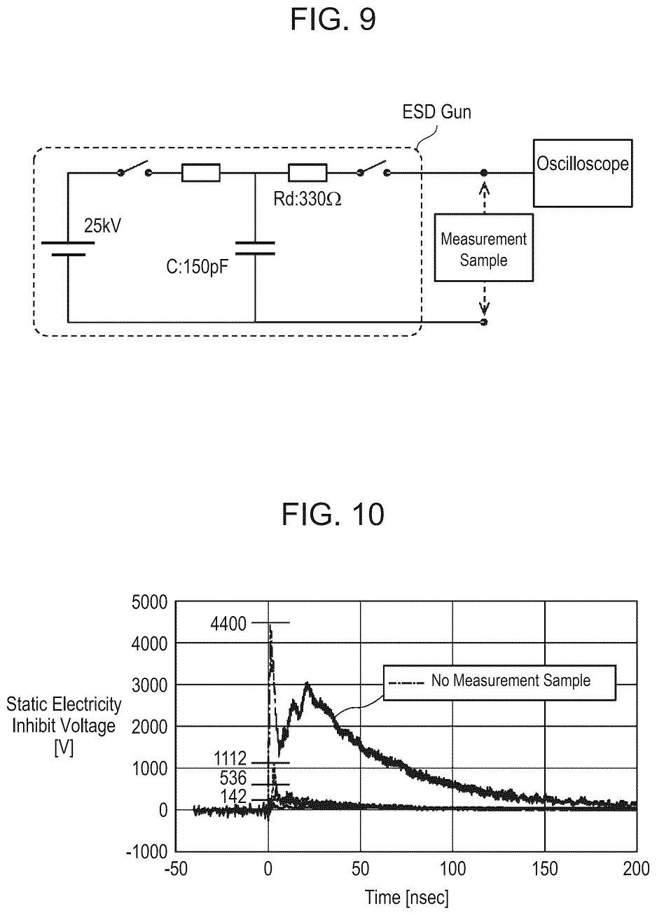

FIG. 9 illustrates a circuit for measuring the static electricity inhibit voltage.

FIG. 9 illustrates an oscilloscope and an equivalent circuit of the ESD gun, which are used to measure the static electricity inhibit voltage. The measurement sample is the MLCC or the MLCV.

In this measurement, the static electricity inhibit voltage of the measurement sample after the ESD voltage of 25 kV was applied to the sample was examined. The lower the static electricity inhibit voltage, the better a property of reducing the static electricity noise.

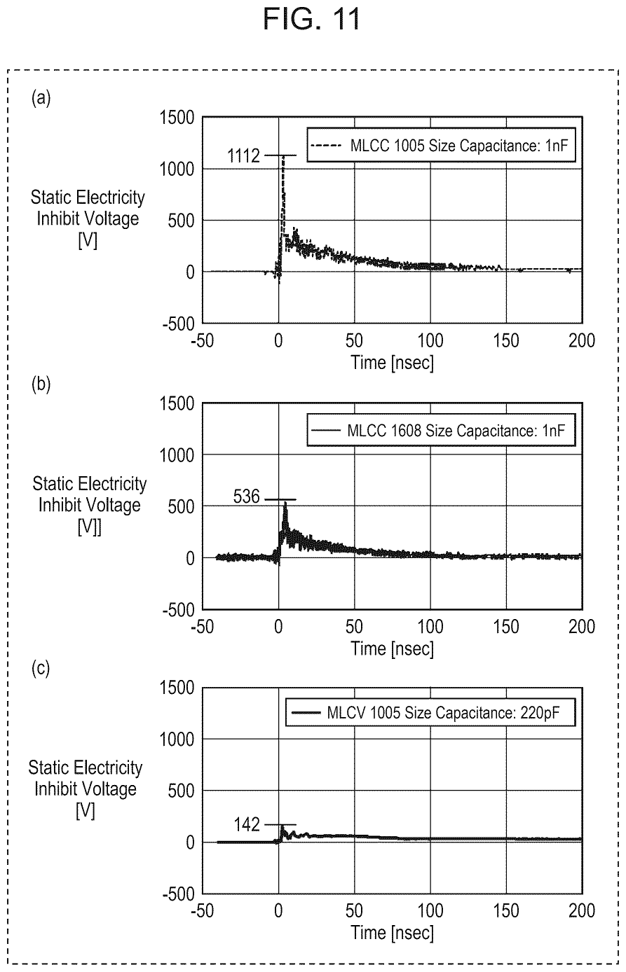

FIG. 10 illustrates static electricity inhibit voltages of the multi-layer ceramic capacitor and the multi-layer ceramic varistor. FIG. 11 illustrates a part of FIG. 10 extracted and enlarged along a vertical axis of FIG. 10.

FIG. 10 illustrates a temporal change of the static electricity inhibit voltage. FIG. 11(a) illustrates a multi-layer ceramic capacitor having a 1005 size and a capacitance of 1 nF used as a measurement sample. FIG. 11(b) illustrates a multi-layer ceramic capacitor having a 1608 size and a capacitance of 1 nF used as a measurement sample. FIG. 11(c) illustrates a multi-layer ceramic varistor having a 1005 size and a capacitance of 220 pF used as a measurement sample.

As illustrated in FIG. 10, when no measurement sample is provided, that is, when the ESD gun is used alone, a maximum value of the static electricity inhibit voltage is very high.

As illustrated in FIG. 11(a), the measurement sample of the multi-layer ceramic capacitor having the 1005 size and the capacitance of 1 nF exhibited the maximum value of the static electricity inhibit voltage of 1112 V. As illustrated in FIG. 11(b), the measurement sample of the multi-layer ceramic capacitor having the 1608 size and the capacitance of 1 nF exhibited the maximum value of the static electricity inhibit voltage of 536 V. The measurement sample of multi-layer ceramic capacitors thus exhibited the static electricity inhibit voltage of a high value, hence hardly reducing static electricity noise.

As illustrated in FIG. 11(c), the measurement sample of the multi-layer ceramic varistor having the 1005 size and the capacitance of 220 pF exhibited the maximum value of the static electricity inhibit voltage of 142, which is lower than those in FIGS. 11(a) and 11(b). The static electricity inhibit voltage of the multi-layer ceramic varistor is about ⅛ of the multi-layer ceramic capacitor having the 1005 size and about ¼ of the multi-layer ceramic capacitor having the 1608 size.

The multi-layer ceramic varistor thus has a lower static electricity inhibit voltage than the multi-layer ceramic capacitor, and reduces the static electricity noise. Therefore, the first varistor V1 and the second varistor V2 functioning as capacitors are multi-layer ceramic varistors enhance the noise resistance of the electronic control system 1.

### Exemplary Embodiment 2

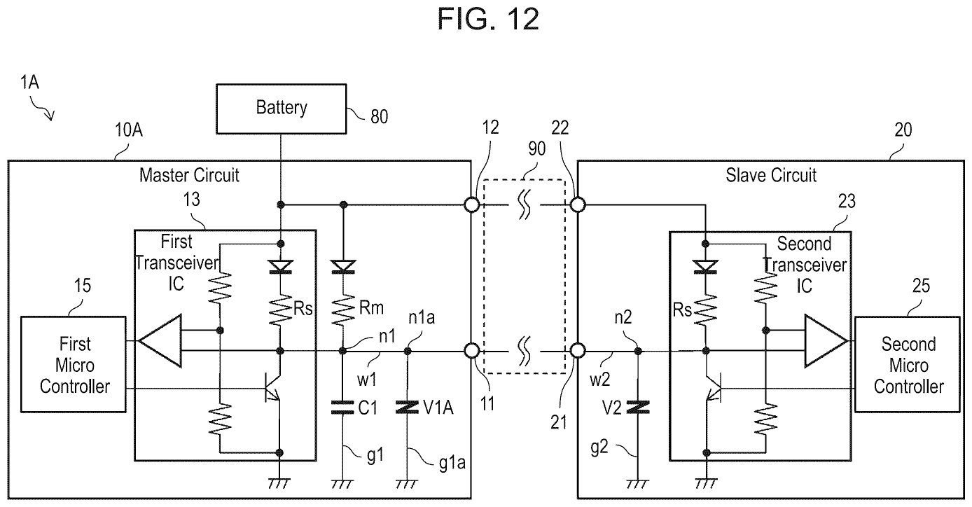

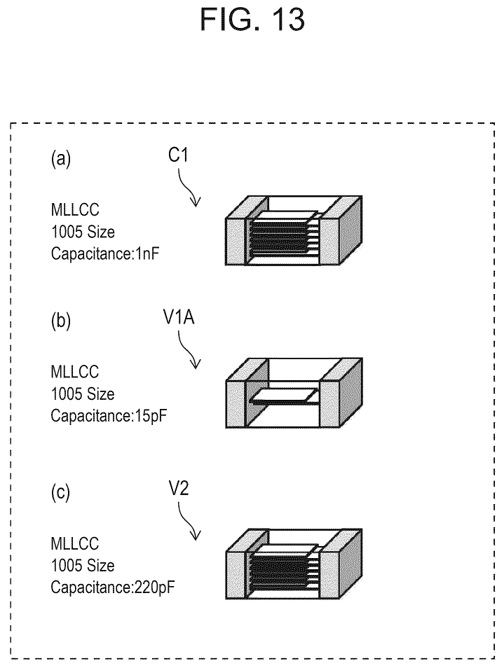

Configuration of Electronic Control System A configuration of an electronic control system 1A according to exemplary Embodiment 2 will be described with reference to FIGS. 12 and 13. In accordance with Embodiment 2, an example in which a master circuit 10A includes a capacitor C1, and a first varistor V1A is connected in parallel to the capacitor C1 will be described.

FIG. 12 is a circuit diagram of the electronic control system 1A according to Embodiment 2. FIG. 13 is a schematic diagram of an example of the capacitor C1 and the first varistor V1A provided in the master circuit 10A and the second varistor V2 provided in the slave circuit 20 of the electronic control system 1A.

As illustrated in FIG. 12, the electronic control system 1A includes a master circuit 10A and the slave circuit 20 which is connected to the master circuit 10A with a bus. The master circuit 10A is connected to the slave circuit 20 via the bus cable 90.

Similarly to Embodiment 1, the slave circuit 20 includes the second microcontroller 25, the second transceiver IC 23, the second communication terminal 21, the second power supply terminal 22, and the second varistor V2. For example, the varistor voltage of the second varistor V2 is 20 V or more.

The master circuit 10A includes the first microcontroller 15, the first transceiver IC 13, the first communication terminal 11, the first power supply terminal 12, the capacitor C1, and the first varistor VIA. The master circuit 10A includes the master resistor Rm. The external battery 80 is connected to the master circuit 10A.

The first microcontroller 15, the first transceiver IC 13, the first communication terminal 11, the first power supply terminal 12, and the master resistor Rm are identical to those in Embodiment 1.

The capacitor C1 and the first varistor VIA are elements for preventing deterioration in communication quality when the communication is performed between the master circuit 10A and the slave circuit 20.

The capacitor C1 is an element for a countermeasure against noise, and is provided in the line g1 connecting the ground to the transmission path w1 which connects the first transceiver IC 13 to the first communication terminal 11. The capacitor C1 has one end connected to the node n1 on the transmission path w1 between the first communication terminal 11 and the first transceiver IC 13, and another end connected to the ground.

The first varistor VIA is connected in parallel to the capacitor C1. The first varistor VIA is provided in the line g1a connecting the ground to the transmission path w1 which connects the first transceiver IC 13 to the first communication terminal 11. The first varistor VIA has one end connected to a node n1a on the transmission path w1 between the first communication terminal 11 and the first transceiver IC 13, and another end connected to the ground. The first varistor VIA causes a current to flow out from the node n1a to the ground by being conducted under a predetermined voltage condition. Therefore, even when a large current flows through the transmission path w1, the current is prevented from flowing into the first transceiver IC 13 and the capacitor C1, thereby protecting the first transceiver IC 13 and the capacitor C1. For example, a varistor voltage of the first varistor VIA is 20 V or more.

In the electronic control system 1A having the above-described configuration, the capacitor C1 is a multi-layer ceramic capacitor, and the size of the capacitor C1 is, for example, a 1005 size (length 1.0 mm, width 0.5 mm, height 0.5 mm) (see FIG. 13(a)). The first varistor V1A and the second varistor V2 are multi-layer ceramic varistors (see FIGS. 13(b) and 13(c)). The total size of the capacitor C1 and the first varistor V1A is smaller than the size of the varistor V1. Accordingly, the master circuit 10A disposed at the end of the vehicle has a smaller size than the master circuit 1A. The size of the second varistor V2 is smaller than the total size of the capacitor C1 and the first varistor VIA. Accordingly, the size of the slave circuit 20 is smaller than the size of the master circuit 10A. Here, the compared size and the total size are sizes equivalent to a mounting area obtained by multiplying each length and width.

The capacitor C1 has a larger capacitance than the second varistor V2, and the first varistor V1A has a smaller capacitance than the second varistor V2. For example, the capacitance of the capacitor C1 is 0.8 nF or more and 1.2 nF or less, the capacitance of the first varistor V1A is 20 pF or less, and the capacitance of the second varistor V2 is 175 pF or more and 250 pF or less.

In accordance with the present embodiment, the capacitor C1 and the first varistor V1A are connected in parallel to each other, and thus it is not necessary to increase a capacitance of the first varistor V1A, and the capacitance of the first varistor V1A may be sufficiently small (for example, 20 pF or less) with respect to the capacitance (for example, 1 nF) of the capacitor C1. In addition, the first varistor V1A has a high ESD resistance, and a multi-layer ceramic capacitor that is weak to static electricity may have a small size.

The electronic control system 1A according to Embodiment 2 includes the master circuit 10A and the slave circuit 20 connected to the master circuit 10A via the bus cable 90. The master circuit 10A includes the first microcontroller 15, the first transceiver IC 13 connected to the first microcontroller 15, the first communication terminal 11 connected to the bus cable 90, the capacitor C1 provided in the line g1 connecting the ground to the transmission path w1 which connects the first transceiver IC 13 to the first communication terminal 11, and the first varistor V1A provided in the line g1a connecting the ground to the transmission path w1. The slave circuit 20 includes the second microcontroller 25, the second transceiver IC 23 connected to the second microcontroller 25, the second communication terminal 21 connected to the bus cable 90, and the second varistor V2 provided in the line g2 connecting the ground to the transmission path w2 which connects the second transceiver IC 23 to the second communication terminal 21.

The capacitor C1 and the first varistor V1A are thus provided in the line g1a connecting the transmission path w1 to the ground, and the second varistor V2 is provided in the line g2 connecting the transmission path w2 to the ground. Even when a large current flows through the transmission path, this configuration prevents the current from flowing into the transceiver IC, accordingly preventing the deterioration in communication quality when the communication is performed between the master circuit 10A and the slave circuit 20.

### SUMMARY

The electronic control system 1 according to the present embodiments includes the master circuit 10 and the slave circuit 20 connected to the master circuit 10 via the bus cable 90. The master circuit 10 includes the first microcontroller 15, the first transceiver IC 13 connected to the first microcontroller 15, the first communication terminal 11 connected to the bus cable 90, and the first varistor V1 provided in the line g1 connecting the ground to the transmission path w1 which connects the first transceiver IC 13 and the first communication terminal 11. The slave circuit 20 includes the second microcontroller 25, the second transceiver IC 23 connected to the second microcontroller 25, the second communication terminal 21 connected to the bus cable 90, and the second varistor V2 provided in the line g2 connecting the ground to the transmission path w2 which connects the second transceiver IC 23 to the second communication terminal 21.

The first varistor V1 is thus provided in the line g1 connecting the transmission path w1 to the ground, and the second varistor V2 is thus provided in the line g2 connecting the transmission path w2 to the ground. Even when a large current flows through the transmission path, this configuration prevents the current from flowing into the transceiver IC, thereby preventing the deterioration in communication quality when the communication is performed between the master circuit 10 and the slave circuit 20.

The capacitance of the first varistor V1 may be larger than the capacitance of the second varistor V2.

By increasing the capacitance of the first varistor V1, for example, even if the number of slave circuits 20 or a length of the bus cable 90 changes, the time constant τ of the communication signal line is substantially within the predetermined range. Therefore, it is possible to provide the electronic control system 1 having a wide application range.

The capacitance of the first varistor V1 may be 0.8 nF or more and 1.2 nF or less, and the capacitance of the second varistor V2 may be 175 pF or more and 250 pF or less.

According to this configuration, for example, even if the number of slave circuits 20 is small and the length of the bus cable 90 is short, the time constant τ of the communication signal line may be substantially within the predetermined range. Therefore, it is possible to provide the electronic control system 1 having a wide application range.

The first varistor V1 and the second varistor V2 may be multi-layer ceramic varistors, and the size of the second varistor V2 may be smaller than the size of the first varistor V1.

This configuration allows the slave circuit 20 to have a smaller size than the master circuit 10.

The master circuit 10A of the electronic control system 1A may further include the capacitor C1 provided in the line connecting the ground to the transmission path w1 which connects the first transceiver IC 13 to the first communication terminal 11.

The capacitor C1 this provided in the line connecting the transmission path w1 to the ground enhances the noise resistance when the communication is performed between the master circuit 10A and the slave circuit 20. In the master circuit 10A, the first varistor V1A is provided in the line connecting the transmission path w1 to the ground, thus securing the ESD resistance.

The capacitance of the capacitor C1 may be larger than the capacitance of the second varistor V2, and the capacitance of the first varistor V1A may be smaller than the capacitance of the second varistor V2.

By increasing the capacitance of the capacitor C1, for example, even if the number of slave circuits 20 or the length of the bus cable 90 changes, the time constant τ of the communication signal line may be substantially within the predetermined range. Therefore, it is possible to provide the electronic control system 1A having a wide application range.

In addition, the capacitance of the capacitor C1 may be 0.8 nF or more and 1.2 nF or less, the capacitance of the first varistor V1 may be 20 pF or less, and the capacitance of the second varistor V2 may be 175 pF or more and 250 pF or less.

According to this configuration, for example, even if the number of slave circuits 20 is small and the length of the bus cable 90 is short, the time constant τ of the communication signal line can be substantially within the predetermined range. Therefore, it is possible to provide the electronic control system 1A having a wide application range.

The capacitor C1 may be a multi-layer ceramic capacitor, the first varistor V1 and the second varistor V2 may be multi-layer ceramic varistors, and the size of the second varistor V2 may be smaller than the total of the size of the capacitor C1 and the size of the first varistor V1.

This configuration allows the slave circuit 20 to have a smaller size than the master circuit 10A.

The varistor voltage of the first varistor V1 may be 20 V or more, and the varistor voltage of the second varistor V2 may be 20 V or more.

According to this configuration, for example, the High voltage (in a range from 8 V to 18 V) which is a recessive of the communication signal, and the Low voltage (0 V) which is a dominant is reliably implemented.

The master circuit 10 may be connected communicably to the slave circuit 20 with one wire out of the plurality of wires provided in the bus cable 90.

This configuration prevents the deterioration in communication quality when the communication is performed between the master circuit 10 and the slave circuit 20 based on the LIN or the CXPI.

The electronic control system 1 may include the master circuit 10 and the slave circuits 20 which are bus-connected to the master circuit 10.

This configuration prevents the deterioration in communication quality when the communication is performed between the master circuit 10 and the slave circuits 20.

### OTHER EMBODIMENT

The electronic control system according to the embodiments and the modifications of the present disclosure has been described above, but the present disclosure is not limited to the embodiments and the modifications. The scope of the present disclosure also includes embodiments obtained by applying various modifications conceived by those skilled in the art to the embodiments and the modifications, and other embodiments constructed by combining some of the components in the embodiments and the modifications, without departing from the gist of the present disclosure.

### INDUSTRIAL APPLICABILITY

An electronic control system according to the present disclosure is useful as an electronic control system that performs the communication based on the LIN or the CXPI.

### REFERENCE MARKS IN THE DRAWINGS

1, 1A electronic control system
10, 10A master circuit
11 first communication terminal
12 first power supply terminal
13 first transceiver IC
15 first microcontroller
20 slave circuit
21 second communication terminal
22 second power supply terminal
23 second transceiver IC
25 second microcontroller
80 battery
90 bus cable
C1 capacitor
g1, g1a, g2 line
n1, n1a, n2 node
Rm master resistor
Rs pull-up resistor
V1, V1A first varistor
V2 second varistor
w1, w2 transmission path

1. An electronic control system comprising a master circuit and a slave circuit connected to the master circuit via a bus cable, wherein
the master circuit includes:
a first microcontroller;
a first transceiver integrated circuit (IC) connected to the first microcontroller;
a first communication terminal connected to the bus cable; and
a first varistor provided in a line connecting a ground to a transmission path which connects the first transceiver IC to the first communication terminal, and the slave circuit includes:
a second microcontroller;
a second transceiver IC connected to the second microcontroller;
a second communication terminal connected to the bus cable; and
a second varistor provided in a line connecting a ground to a transmission path which connects the second transceiver IC to the second communication terminal.

2. The electronic control system according to claim 1, wherein a capacitance of the first varistor is larger than a capacitance of the second varistor.

3. The electronic control system according to claim 1, wherein
a capacitance of the first varistor is 0.8 nF or more and 1.2 nF or less, and
a capacitance of the second varistor is 175 pF or more and 250 pF or less.

4. The electronic control system according to claim 2, wherein
the first varistor and the second varistor are multi-layer ceramic varistors, and
a size of the second varistor is smaller than a size of the first varistor.

5. The electronic control system according to claim 1, wherein the master circuit further includes a capacitor provided in the line connecting the ground and the transmission path which connects the first transceiver IC to the first communication terminal.

6. The electronic control system according to claim 5, wherein
a capacitance of the capacitor is larger than a capacitance of the second varistor, and
a capacitance of the first varistor is smaller than the capacitance of the second varistor.

7. The electronic control system according to claim 5, wherein
a capacitance of the capacitor is 0.8 nF or more and 1.2 nF or less,
a capacitance of the first varistor is 20 pF or less, and
a capacitance of the second varistor is 175 pF or more and 250 pF or less.

8. The electronic control system according to claim 5, wherein
the capacitor is a multi-layer ceramic capacitor,
the first varistor and the second varistor are multi-layer ceramic varistors, and
a size of the second varistor is smaller than a total of a size of the capacitor and a size of the first varistor.

9. The electronic control system according to claim 1, wherein
a varistor voltage of the first varistor is 20 V or more, and
a varistor voltage of the second varistor is 20 V or more.

10. The electronic control system according to claim 1, wherein the master circuit is connected to the slave circuit communicably with a wire out of a plurality of wires provided in the bus cable.

11. The electronic control system according to claim 1, further comprising:
the master circuit; and
a plurality of slave circuits connected to the master circuit, each of the plurality of slave circuits being the slave circuit.
